(19) United States
(12) Patent Application Publication
(10) Pub. No.: US 2026/0018223 A1
(43) Pub. Date: Jan. 15, 2026

(54) ANTIFUSE-TYPE NON-VOLATILE MEMORY AND ASSOCIATED DRIVING CIRCUIT

(71) Applicant: eMemory Technology Inc., Hsin-Chu (TW)

(72) Inventor: Chieh-Tse LEE, Hsinchu County (TW)

(21) Appl. No.: 19/266,387

(22) Filed: Jul. 11, 2025

Related U.S. Application Data
(60) Provisional application No. 63/671,307, filed on Jul. 15, 2024.

(51) Int. Cl. G11C 17/18; G11C 17/16

(52) U.S. Cl. CPC G11C 17/18; G11C 17/16

(57) ABSTRACT

An antifuse-type non-volatile memory includes a memory cell array, a driving circuit, a first voltage power supply and a second voltage power supply. The memory cell array includes a first sub-array and a second sub-array. All memory cells in the first sub-array are connected with a first antifuse control line and a first following control line. All memory cells in the second sub-array are connected with a second antifuse control line and a second following control line. The first voltage power supply provides a first voltage to the first antifuse control line and the second antifuse control line through a first antifuse control line driver and a second antifuse control line driver of the driving circuit. The second voltage power supply provides a second voltage to the first following control line and the second following control line directly.

This application claims the benefit of U.S. provisional application Ser. No. 63/671,307, filed Jul. 15, 2024, the subject matters of which is incorporated herein by reference.

### FIELD OF THE INVENTION

The present invention relates to a non-volatile memory, and more particularly to an antifuse-type non-volatile memory and an associated driving circuit.

### BACKGROUND OF THE INVENTION

As known, non-volatile memories can be classified into a multi-time programming memory (also referred as a MTP memory), a one time programming memory (also referred as an OTP memory) and a mask read only memory (also referred as a Mask ROM).

Generally, the MTP memory can be programmed many times, and the stored data of the MTP memory can be modified many times. On the contrary, the OTP memory can be programmed once. After the OTP memory is programmed, the stored data cannot be modified. Moreover, after the Mask ROM leaves the factory, all stored data have been recorded therein. The user is only able to read the stored data from the Mask ROM, but is unable to program the Mask ROM.

For example, an antifuse-type non-volatile memory is one type of OTP memory. Before a memory cell of the antifuse-type non-volatile memory is programmed, the antifuse-type non-volatile memory has a high-resistance storage state. After the memory cell of the antifuse-type non-volatile memory is programmed, the stored data cannot be modified.

For example, an antifuse-type non-volatile memory cell is disclosed in U.S. Pat. No. 11,735,266, which is entitled “Antifuse-type one time programming memory cell and cell array structure with same”. In this patent, various types of antifuse-type non-volatile memory cells are introduced.

FIG. 1A is a schematic circuit diagram illustrating a conventional antifuse-type non-volatile memory cell. As shown in FIG. 1A, the antifuse-type non-volatile memory cell 100 comprises an antifuse transistor M_{AF}, a following transistor M_{FL} and a select transistor M_{S}.

The memory cell 100 has four terminals. The first drain/source terminal of the antifuse transistor M_{AF} is in a floating state. The gate terminal of the antifuse transistor M_{AF} is served as a first terminal of the memory cell 100 and connected with an antifuse control line AF. The second drain/source terminal of the antifuse transistor M_{AF} is connected with the first drain/source terminal of the following transistor M_{FL}. The gate terminal of the following transistor M_{FL} is served as a second terminal of the memory cell 100 and connected with a following control line FL. The second drain/source terminal of the following transistor M_{FL} is connected with the first drain/source terminal of the select transistor M_{S}. The gate terminal of the select transistor M_{S} is served as a third terminal of the memory cell 100 and connected with a word line WL. The second drain/source terminal of the select transistor M_{S} is served as a fourth terminal of the memory cell 100 and connected with a bit line BL.

When a program action is performed, appropriate bias voltages are provided to the memory cell 100. Consequently, the memory cell 100 can be controlled to be in a ruptured state or an unruptured state during a program action. The ruptured state is a storage state corresponding to a low resistance value, and the unruptured state is a storage state corresponding to a high resistance value.

FIG. 1B schematically illustrates associated bias voltages for controlling the memory cell to be in a ruptured state. FIGS. 1C, 1D and 1E schematically illustrate associated bias voltages for controlling the memory cell to be in an unruptured state.

Please refer to FIG. 1B. When the program action is performed, the bit line BL receives a ground voltage (0V), the word line WL receives an on voltage V_{ON}, the following control line FL receives a conducting voltage V_{CD}, and the antifuse control line AF receives a program voltage V_{PP}. For example, the program voltage V_{PP} is 6V, the conducting voltage V_{CD} is 1.8V, and the on voltage V_{ON} is 1.4V.

Please refer to FIG. 1B again. When the select transistor M_{S} is turned on and the following transistor M_{FL} is in a conducting state, the ground voltage (0V) received by the bit line BL is transferred to the first drain/source terminal of the antifuse transistor M_{AF}. Consequently, the voltage stress withstood by the antifuse transistor M_{AF} is equal to the program voltage V_{PP}. Under this circumstance, a gate dielectric layer of the antifuse transistor M_{AF} is ruptured, and the memory cell 100 generates a program current I_{P}. The program current I_{P} flows from the antifuse control line AF to the bit line BL through the antifuse transistor M_{AF}, the following transistor M_{FL} and the select transistor M_{S}. Consequently, the memory cell 100 is in the ruptured state.

Please refer to FIG. 1C. When the program action is performed, the bit line BL receives the ground voltage (0V), the word line WL receives an off voltage VOFF, the following control line FL receives the conducting voltage V_{CD}, and the antifuse control line AF receives a program voltage V_{PP}. For example, the off voltage VOFF is 0V.

As shown in FIG. 1C, the select transistor M_{S} is turned off. Consequently, the ground voltage (0V) received by the bit line BL cannot be transferred to the first drain/source terminal of the antifuse transistor M_{AF}. The gate dielectric layer of the antifuse transistor M_{AF} does not withstand the voltage stress of the program voltage V_{PP}. Under this circumstance, the gate dielectric layer of the antifuse transistor M_{A}F is not ruptured, and the program current I_{P} is nearly zero. Consequently, the memory cell 100 is in the unruptured state.

Of course, there are other ways to control the memory cell 100 to be maintained in the unruptured state.

Please refer to FIG. 1D. When the program action is performed, the bit line BL is in a floating state, the word line WL receives the on voltage V_{ON}, the following control line FL receives the conducting voltage V_{CD}, and the antifuse control line AF receives the program voltage V_{PP}. The gate dielectric layer of the antifuse transistor M_{AF} does not withstand the voltage stress of the program voltage V_{PP}. Under this circumstance, the gate dielectric layer of the antifuse transistor M_{AF} is not ruptured.

Please refer to FIG. 1E. When the program action is performed, the bit line BL receives a preset voltage V_{A}, the word line WL receives the on voltage V_{ON}, the following control line FL receives the conducting voltage V_{CD}, and the antifuse control line AF receives the program voltage V_{PP}. The voltage difference between the program voltage V_{PP} and the preset voltage V_{A} is lower than the voltage stress that can be withstood by the antifuse control line AF. For example, the gate dielectric layer of the antifuse transistor M_{AF} can withstand the voltage stress of 4V, and the program voltage V_{PP} is 6V. That is, the voltage difference between the program voltage V_{PP} and the preset voltage V_{A} needs to comply with the relationship: |V_{PP}−V_{A}|<4V. That is, the preset voltage V_{A} is set to be in the range between 2V and 10V.

Please refer to FIG. 1E again. When the select transistor M_{S} is turned on, the preset voltage V_{A} received by the bit line BL is transferred to the first drain/source terminal of the antifuse transistor M_{AF}. Consequently, the voltage stress withstood by the antifuse transistor M_{AF} is equal to |V_{PP}−V_{A}|. Under this circumstance, the gate dielectric layer of the antifuse transistor M_{AF} is not ruptured, and the program current I_{P} is nearly zero. Consequently, the memory cell 100 is in the unruptured state.

When a read action is performed, appropriate bias voltages are provided to the memory cell 100. According to a read current, the memory cell is determined to be in the ruptured state or the unruptured state. FIGS. 1F and 1G schematically illustrates associated bias voltages for reading the state memory cell during the read action.

Please refer to FIGS. 1F and 1G. When the read action is performed, the bit line BL receives the ground voltage (0V), the word line WL receives the on voltage V_{ON}, the following control line FL receives the conducting voltage V_{CD}, and the antifuse control line AF receives a read voltage VR. For example, the read voltage VR is 1.2V.

In the situation of FIG. 1F, the gate dielectric layer of the antifuse transistor M_{AF} is ruptured, and the select transistor M_{S} is turned on. Consequently, the following transistor M_{FL} is in the conducting state, and the memory cell 100 generates a read current IR. The read current IR flows from the antifuse transistor M_{AF} to the bit line BL through the antifuse transistor M_{AF}, the following transistor M_{FL} and the select transistor M_{S}.

In the situation of FIG. 1G, the gate dielectric layer of the antifuse transistor M_{AF} is not ruptured. Consequently, the magnitude of the read current IR is very low (e.g., nearly zero).

In other words, when the read action is performed, the storage state of the memory cell 100 can be determined according to the magnitude of the read current IR generated by the memory cell 100. For example, the non-volatile memory includes a current comparator. The first terminal of the current comparator receives the read current IR. The second terminal of the current comparator receives a reference current. If the read current IR is higher than the reference current, the current comparator outputs a first logic level, indicating that the memory cell 100 is in the ruptured state. Whereas, if the read current IR is lower than the reference current, the current comparator outputs a second logic level, indicating that the memory cell 100 is in the unruptured state.

In FIG. 1A, the memory cell 100 includes three transistors. In addition, the following transistor M_{FL} is coupled between the antifuse transistor M_{AF} and the select transistor M_{S}. In fact, the memory cell may include a plurality of following transistors, and the plurality of following transistors are coupled between the antifuse transistor M_{AF} and the select transistor M_{S}.

For example, the memory cell includes a first following transistor, a second following transistor, an antifuse transistor and a select transistor. In other words, the memory cell includes four transistors, and the memory cell has five terminals. The first following transistor and the second following transistor are coupled between the antifuse transistor and the select transistor. The gate terminal of the first following transistor is connected with a first following control line. The gate terminal of the second following transistor is connected with a second following control line. The methods of controlling the program action and the read action on the four-transistor memory cell are similar to those of FIG. 1B to FIG. 1G, and not redundantly described herein.

### SUMMARY OF THE INVENTION

An embodiment of the present invention provides an antifuse-type non-volatile memory. The antifuse-type non-volatile memory includes a memory cell array, a driving circuit, a first voltage power supply and a second voltage power supply. The memory cell array includes a first sub-array and a second sub-array. Each of the first sub-array and the second sub-array includes a plurality of memory cells. The plurality of memory cells in the first sub-array are connected with a first antifuse control line and a first following control line. In addition, n memory cells in a first row of the first sub-array are connected with a first word line, and the n memory cells in the first row of the first sub-array are respectively connected with n bit lines. The plurality of memory cells in the second sub-array are connected with a second antifuse control line and a second following control line. In addition, n memory cells in a first row of the second sub-array are connected with a second word line, and the n memory cells in the first row of the second sub-array are respectively connected with the n bit lines, wherein n is a positive integer greater than 1. The driving circuit includes a first antifuse control line driver, a second antifuse control line driver, a word line driver and a bit line driver. The first antifuse control line driver is connected with the first antifuse control line. The second antifuse control line driver is connected with the second antifuse control line driver. The word line driver is connected with the first word line and the second word line. The bit line driver is connected with the n bit lines. An output terminal of the first voltage power supply is connected with the first antifuse control line driver and the second antifuse control line driver. An output terminal of the second voltage power supply is connected with the first following control line and the second following control line. When the antifuse-type non-volatile memory enters a program mode, the first voltage power supply provides a program voltage to the first antifuse control line driver and the second antifuse control line driver, and the second voltage power supply provides a conducting voltage to the first following control line and the second following control line. When the antifuse-type non-volatile memory enters the program mode, and before a program cycle, the first antifuse control line driver does not output the program voltage to the first antifuse control line, and the second antifuse control driver does not output the program voltage to the second antifuse control line.

Numerous objects, features and advantages of the present invention will be readily apparent upon a reading of the following detailed description of embodiments of the present invention when taken in conjunction with the accompanying drawings. However, the drawings employed herein are for the purpose of descriptions and should not be regarded as limiting.

### BRIEF DESCRIPTION OF THE DRAWINGS

The above objects and advantages of the present invention will become more readily apparent to those ordinarily skilled in the art after reviewing the following detailed description and accompanying drawings, in which:

FIG. 1A (prior art) is a schematic circuit diagram illustrating a conventional antifuse-type non-volatile memory cell;

FIG. 1B (prior art) schematically illustrates associated bias voltages for controlling the memory cell to be in a ruptured state;

FIGS. 1C, 1D and 1E (prior art) schematically illustrates associated bias voltages for controlling the memory cell to be in an unruptured state;

FIGS. 1F and 1G (prior art) schematically illustrates associated bias voltages for reading the state memory cell during the read action;

FIG. 2 is a schematic circuit diagram illustrating the architecture of an antifuse-type non-volatile memory according to a first embodiment of the present invention;

FIG. 3A schematically illustrates associated bias voltages for performing a program action of the antifuse-type non-volatile memory according to the first embodiment of the present invention;

FIG. 3B is a schematic timing waveform diagram illustrating associated signals of the antifuse-type non-volatile memory of the first embodiment in the program mode;

FIG. 4 is a schematic circuit diagram illustrating the architecture of an antifuse-type non-volatile memory according to a second embodiment of the present invention;

FIG. 5A schematically illustrates associated bias voltages for performing a program action of the antifuse-type non-volatile memory according to the second embodiment of the present invention; and

FIG. 5B is a schematic timing waveform diagram illustrating associated signals of the antifuse-type non-volatile memory of the second embodiment in the program mode.

### DETAILED DESCRIPTION OF PREFERRED EMBODIMENTS

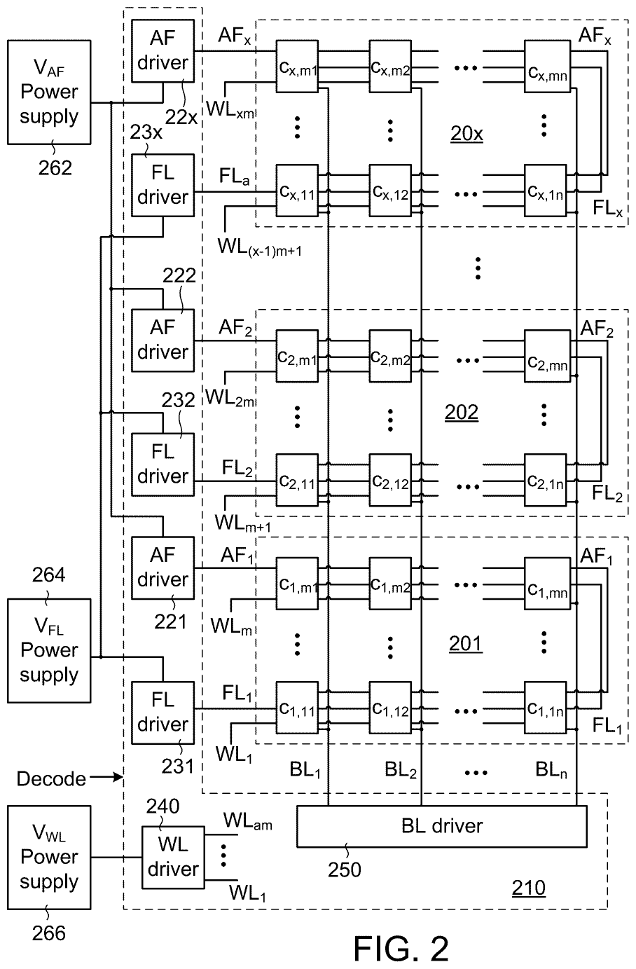

FIG. 2 is a schematic circuit diagram illustrating the architecture of an antifuse-type non-volatile memory according to a first embodiment of the present invention. As shown in FIG. 2, the antifuse-type non-volatile memory includes a memory cell array, a driving circuit 210 and a power supplying circuit.

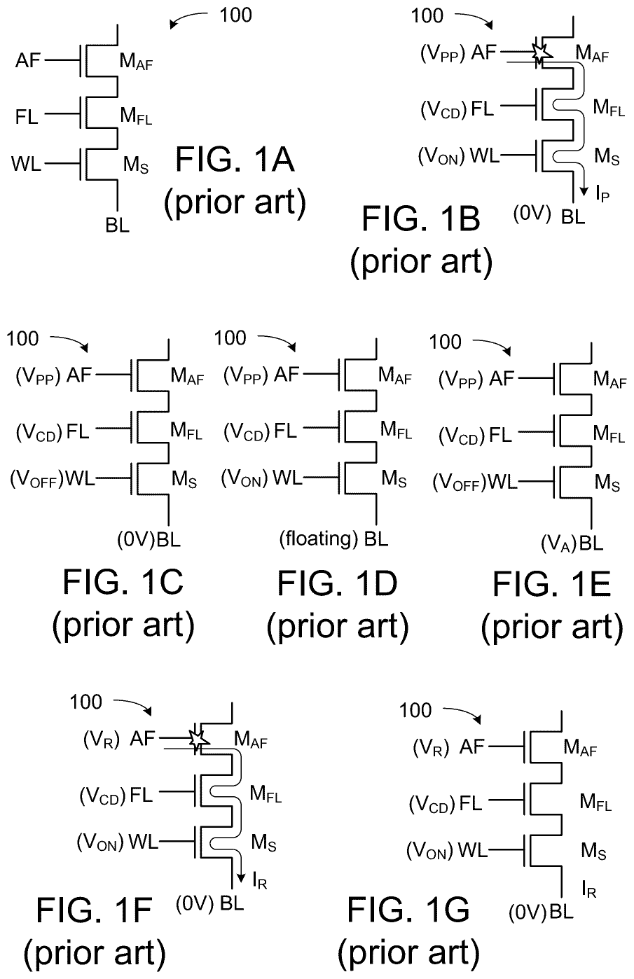

The memory cell array includes x sub-arrays 201˜20x, wherein x is a positive integer greater than 1. These sub-arrays 201˜20x have the same structure. Each of the sub-arrays 201˜20x includes m×n memory cells, wherein m and n are positive integers greater than 1. In other words, the memory cell array includes x×m×n memory cells. In addition, the structure of each memory cell in the memory cell array is the same as the memory cell 100 shown in FIG. 1A. Each sub-array can also be referred to as a sector. In other words, the memory cell array includes x sectors.

In the sub-array 201, the first terminals of all memory cells c_{1,1i}˜c_{1,mn} are connected with the same antifuse control line AF₁, and the second terminals of all memory cells c_{1,11}˜c_{i,mn} are connected with the same following control line FL₁. The third terminals of n memory cells c_{1,11}˜c_{1,1n} in the first row are connected with a word line WL₁, and the fourth terminals of the n memory cells c_{1,11}˜c_{1,1n} in the first row are respectively connected with the corresponding bit lines BL₁˜BLₙ. The rest may be deduced by analogy. The third terminals of the n memory cells c_{1,m1}˜c_{i,mn} in the m-th row are connected with a word line WLₘ, and the fourth terminals of the n memory cells c_{1,m1}˜c_{i,mn} in the m-th row are respectively connected with the corresponding bit lines BL₁˜BLₙ.

In the sub-array 202, the first terminals of all memory cells c_{2,11}˜c_{2,mn} are connected with the same antifuse control line AF₂, and the second terminals of all memory cells c_{2,11}˜c_{2,mn} are connected with the same following control line FL₂. The third terminals of n memory cells c_{2,11}˜c_{2,1n} in the first row are connected with a word line WLₘ₊₁, and the fourth terminals of the n memory cells c_{2,11}˜c_{2,1n} in the first row are respectively connected with the corresponding bit lines BL₁˜BLₙ. The rest may be deduced by analogy. The third terminals of the n memory cells c_{2,m1}˜c_{2,mn} in the m-th row are connected with a word line WL₂ₘ, and the fourth terminals of the n memory cells c_{2,m1}˜c_{2,mn} in the m-th row are respectively connected with the corresponding bit lines BL₁˜BLₙ.

The rest may be deduced by analogy. In the sub-array 20x, the first terminals of all memory cells c_{x,11}˜c_{x,mn} are connected with the same antifuse control line AFₓ, and the second terminals of all memory cells c_{x,11}˜c_{x,mn} are connected with the same following control line FLₓ. The third terminals of n memory cells c_{x,11}˜c_{x,1n} in the first row are connected with a word line WL₍ₓ₋₁₎ₘ₊₁, and the fourth terminals of the n memory cells c_{x,11}˜c_{x,1n} in the first row are respectively connected with the corresponding bit lines BL₁˜BLₙ. The rest may be deduced by analogy. The third terminals of the n memory cells c_{x,m1}˜c_{x,mn} in the m-th row are connected with a word line WLₓₘ, and the fourth terminals of the n memory cells c_{x,m1}˜c_{x,mn} in the m-th row are respectively connected with the corresponding bit lines BL₁˜BLₙ.

The driving circuit 210 of the antifuse-type non-volatile memory receives a decoding signal Decode. The driving circuit 210 includes x antifuse control line drivers (hereinafter referred to as AF drivers) 221˜22x, x following control line drivers (hereinafter referred to as FL drivers) 231˜23x, a word line driver (hereinafter referred to as a WL driver) 240 and a bit line driver (hereinafter referred to as a BL driver) 250. The AF drivers 221˜22x are respectively connected with the corresponding antifuse control lines AF₁-AFₓ. The FL drivers 231˜23x are respectively connected with the corresponding following control lines FL₁˜FLₓ. The WL driver 240 is connected with all word lines WL₁˜WLₐₘ. The BL driver 250 is connected with all bit lines BL₁˜BLₙ.

The power supplying circuit of the antifuse-type non-volatile memory includes a VAF power supply 262, a VFL power supply 264, and a V_{WL} power supply 266. The AF drivers 221˜22x are connected with the output terminal of the VAF power supply 262 to receive a first voltage VAF. The FL drivers 231˜23x are connected with the output terminal of the VFL power supply 264 to receive a second voltage VFL. The WL driver 240 is connected with the output terminal of the V_{WL} power supply 266 to receive a third voltage V_{WL}.

For example, when the antifuse-type non-volatile memory enters a program mode, the first voltage VAF from the VAF power supply 262 is the program voltage V_{PP}, the second voltage VFL from the VFL power supply 264 is the conducting voltage V_{CD}, and the third voltage V_{WL} from the V_{WL} power supply 266 is the on voltage V_{ON}. When the antifuse-type non-volatile memory enters a read mode, the first voltage VAF from the VAF power supply 262 is the read voltage VR, the second voltage VFL from the VFL power supply 264 is the conducting voltage V_{CD}, and the third voltage V_{WL} from the V_{WL} power supply 266 is the on voltage V_{ON}.

When the program action or the read action is performed, at least one selected memory cell in the memory cell array is determined according to the decoding signal Decode. Furthermore, the driving circuit 210 also controls the corresponding AF drivers 221˜22x and FL drivers 231˜23x according to the decoding signal.

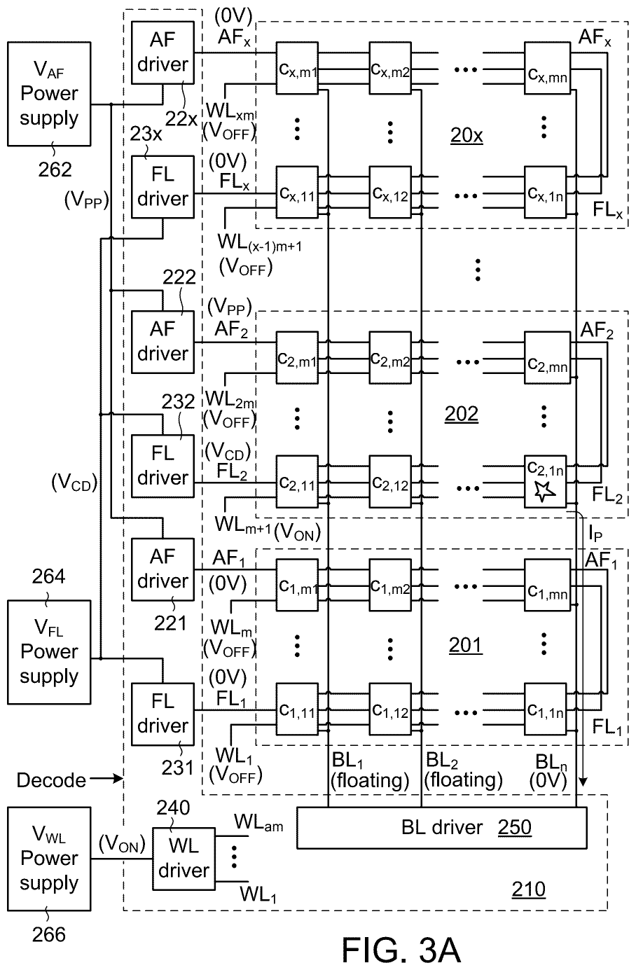

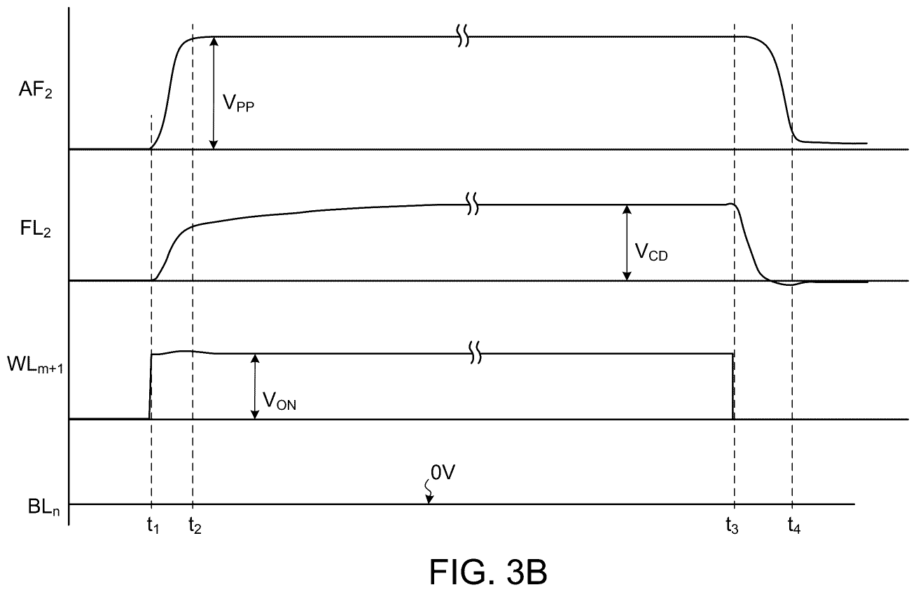

FIG. 3A schematically illustrates associated bias voltages for performing a program action of the antifuse-type non-volatile memory according to the first embodiment of the present invention. For example, when the program action is performed on the antifuse-type non-volatile memory, the first row in the sub-array 202 is the selected row, and the memory cell c_{2,1n} is the selected memory cell. In the program mode, the VAF power supply 262 provides the program voltage V_{PP} to the AF drivers 221˜22x, the VFL power supply 264 provides the conducting voltage V_{CD} to the FL drivers 231˜23x, and the V_{WL} power supply 266 provides the on voltage V_{ON} to the WL driver 240.

During the program action, only the AF driver 222 and the FL driver 232 connected with the sub-array 202 are enabled according to the decoding signal Decode. However, the other AF drivers 221, 22x and the other FL drivers 231, 23x connected with the other sub-arrays 201, 20x are disabled. In other words, only the AF driver 222 outputs the program voltage V_{PP} to the antifuse control line AF₂, and only the FL driver 232 outputs the conducting voltage V_{CD} to the following control lines FL₂. Since the other AF drivers 221, 22x are disabled, the AF drivers 221, 22x do not outputs the program voltage V_{PP} to the antifuse control lines AF₁, AFₓ. Similarly, since the other FL drivers 231, 23x are disabled, the FL drivers 231, 23x do not output the conducting voltage V_{CD} to the following control lines FL₁, FLₓ. For example, the antifuse control lines AF₁, AFₓ and the following control lines FL₁, FLₓ receive the ground voltage (0V).

Furthermore, according to the decoding signal Decode, the WL driver 240 outputs the on voltage V_{ON} to the word line WLₘ₊₁, and the WL driver 240 outputs the off voltage VOFF to other word lines. Consequently, the first row in the sub-array 202 is the selected row. Furthermore, the BL driver 250 outputs the ground voltage (0V) to the bit line BLₙ, and the other bit lines are in the floating state. Consequently, in the sub-array 202, the memory cell c_{2,1n} in the first row is the selected memory cell. The selected memory cell c_{2,1n} generates a program current 1P. In addition, the selected memory cell c_{2,1n} is programmed to the ruptured state.

Furthermore, according to the decoding signal Decode, the BL driver 250 may also output the ground voltage (0V) to more bit lines. For example, when the program action is performed, the BL driver 250 outputs the ground voltage (0V) to the bit line BL₁ and the bit line BLₙ. The other bit lines are in the floating state. Meanwhile, the memory cell c_{2,11} and the memory cell c_{2,1n} are selected memory cells, and these two selected memory cells are programmed into the ruptured state.

FIG. 3B is a schematic timing waveform diagram illustrating associated signals of the antifuse-type non-volatile memory of the first embodiment in the program mode. When the antifuse-type non-volatile memory enters the program mode, multiple program actions can be performed. During each program action, the memory cell is selected according to the decoding signal Decode. Consequently, the corresponding FL driver and the corresponding AF driver are enabled, and the program action is performed on the selected memory cell.

Each program action includes a program cycle. After the program cycle, the selected memory cell will be programmed to the ruptured state. As shown in FIG. 3B, the time period between the time point t₁ and the time point t₃ is the program cycle of one program action. That is, the program action starts at the time point t₁, and the program action ends at the time point t₃. Of course, after the time point t₃, another program action is performed again, and another program cycle starts.

Please refer to FIG. 3B. Before the time point t₁ (i.e., before the program cycle), the AF driver 222 does not output the program voltage V_{PP} to the antifuse control line AF₂, the FL driver 232 does not output the conducting voltage V_{CD} to the following control lines FL₂, and the WL driver 240 does not output the on voltage V_{ON} to the word line WL_{m+1.}

At the time point t₁, according to the decoding signal Decode, the WL driver 240 outputs the on voltage V_{ON} to the word line WLₘ₊₁, the BL driver 250 outputs the ground voltage (0V) to the bit line BLₙ, the AF driver 222 outputs the program voltage V_{PP} to the antifuse control line AF₂, and the FL driver 232 outputs the conducting voltage V_{CD} to the following control lines FL₂. That is, the memory cell c_{2,1n} in the sub-array 202 is the selected memory cell. Furthermore, in the program cycle, the selected memory cell c_{2,1n} will be programmed to the ruptured state.

Generally, the program voltage V_{PP} is higher than the conducting voltage V_{CD}. Consequently, the AF driver 222 has the higher driving capability, and the FL driver 232 has the lower driving capability. Due to the design difference between the AF driver 222 and the FL driver 232, a signal timing difference will be caused. For example, in the time interval between the time point t₁ and the time point t₂, the voltage received by the antifuse control line AF₂ rises to the program voltage V_{PP} quickly, but the voltage received by the following control lines FL₂ rises slowly. Furthermore, at the end of the program action (i.e., at the time point t₃), the voltage received by the following control lines FL₂ drops from the conducting voltage V_{CD} to the ground voltage (0V) quickly, but the voltage received by the antifuse control line AF₂ drops from the program voltage V_{PP} slowly and drops to the ground voltage (0V) at the time point t₄.

Generally, the signal timing difference between the program voltage V_{PP} and the conducting voltage V_{CD} may cause damage to the memory cell or result in program disturbance. For example, in the time interval between the time point t₁ and the time point t₂, the voltage received by the following control lines FL₂ has not reached the conducting voltage V_{CD}. Consequently, the following transistor M_{FL} in the selected memory cell c_{2,1n} is not in the conducting state. Under this circumstance, the following transistor M_{FL} in the selected memory cell c_{2,1n} may be damaged by the voltage stress shock of the program voltage V_{PP}, or the occurrence of the program disturbance leads to program failure. Similarly, in the time interval between the time point t₃ and the time point t₄, the selected memory cell c_{2,1n} may also be damaged.

In order to overcome the above drawbacks, a FL driver 232 with a larger driving capability can be designed. However, as the driving capability of the FL driver 232 increases, the size of the FL driver 232 will increase. Alternatively, the AF driver 222 is equipped with a delay circuit to control the rising/falling time of the program voltage V_{PP}. However, this design makes the structure of the AF driver 222 more complicated.

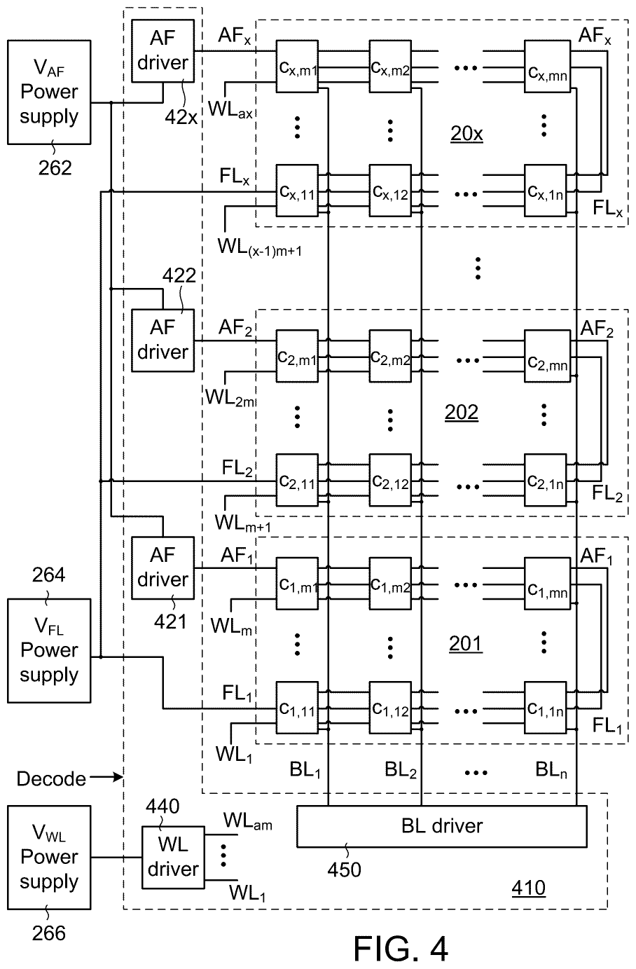

FIG. 4 is a schematic circuit diagram illustrating the architecture of an antifuse-type non-volatile memory according to a second embodiment of the present invention. As shown in FIG. 4, the antifuse-type non-volatile memory includes a memory cell array, a driving circuit 410 and a power supplying circuit. The memory cell array includes a plurality of sub-arrays 201˜20x. The memory cell array and the power supplying circuit in the antifuse-type non-volatile memory of this embodiment are identical to memory cell array and the power supplying circuit in the antifuse-type non-volatile memory of the first embodiment, and not redundantly described herein.

The driving circuit 410 of the antifuse-type non-volatile memory receives a decoding signal Decode. The driving circuit 410 includes x AF drivers 421˜42x, a WL driver 440 and a BL driver 450. The AF drivers 421˜42x are respectively connected with the corresponding antifuse control lines AF₁-AFₓ. The WL driver 440 is connected with all word lines WL₁˜WLₐₘ. The BL driver 450 is connected with all bit lines BL₁˜BLₙ.

In the memory cell array of this embodiment, the second terminals of all memory cells c_{1,11}˜c_{a,mn} are connected with the output terminal of the VFL power supply 264 to receive the second voltage VFL. That is, all following control lines FL₁˜FLₓ are directly connected to the output terminal of the VFL power supply 264 to receive the second voltage VFL. When compared with the antifuse-type non-volatile memory of the first embodiment, the driving circuit 410 in the antifuse-type non-volatile memory of the first embodiment is not equipped with the FL driver. Consequently, the size of the driving circuit 410 can be largely reduced.

When the program action or the read action is performed, at least one selected memory cell in the memory cell array is determined according to the decoding signal Decode. Furthermore, the driving circuit 410 also controls the corresponding AF drivers 421˜42x according to the decoding signal.

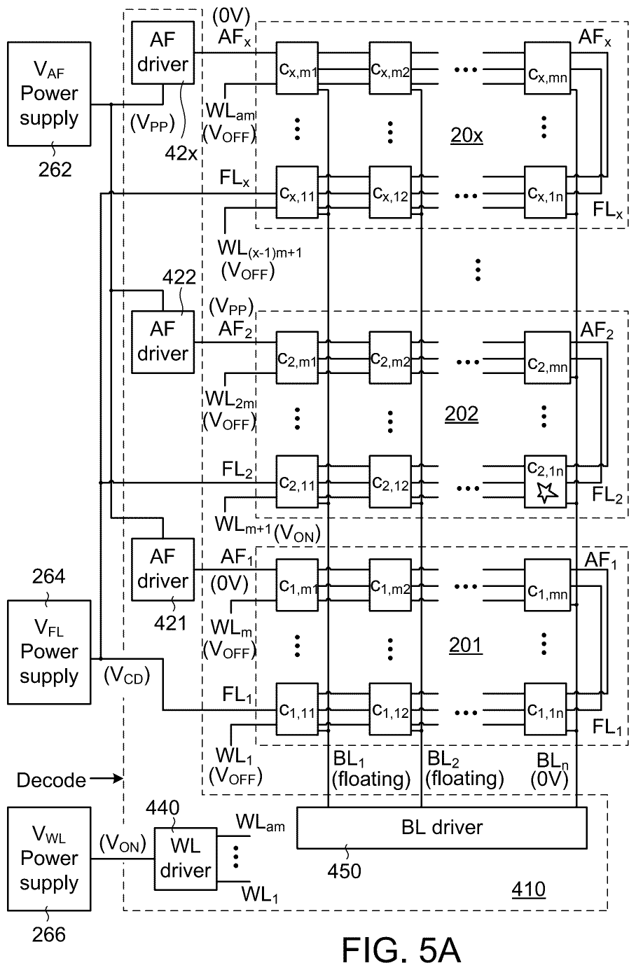

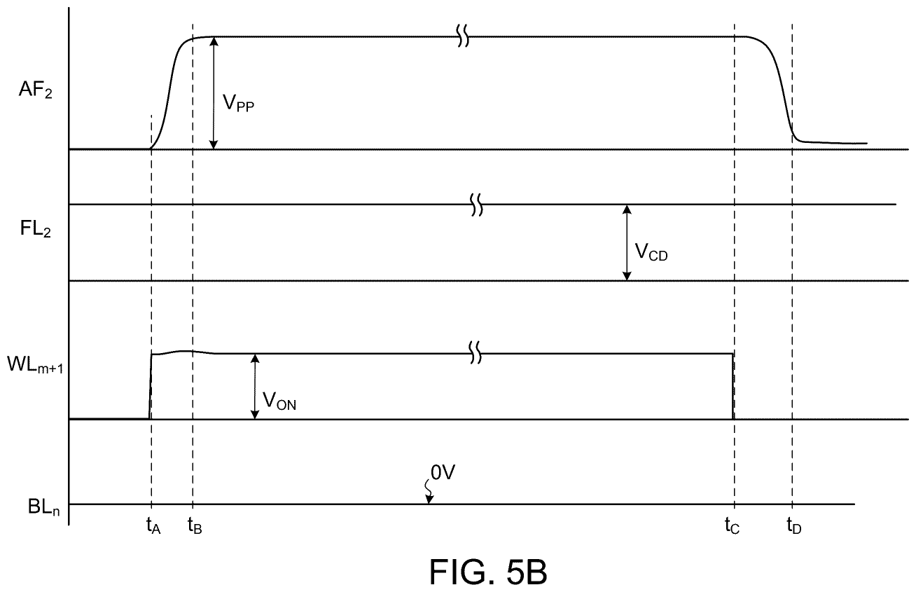

FIG. 5A schematically illustrates associated bias voltages for performing a program action of the antifuse-type non-volatile memory according to the second embodiment of the present invention. For example, when the program action is performed on the antifuse-type non-volatile memory, the first row in the sub-array 202 is the selected row, and the memory cell c_{2,1n} is the selected memory cell.

In the program mode, the VAF power supply 262 provides the program voltage V_{PP} to the AF drivers 221˜22x, the VFL power supply 264 provides the conducting voltage V_{CD} to all following control lines FL₁˜FLₓ, and the V_{WL} power supply 266 provides the on voltage V_{ON} to the WL driver 240. Under this circumstance, the following control lines FL₁˜FLₓ of all sub-arrays 201˜20x receive the conducting voltage V_{CD}.

During the program action, only the AF driver 422 connected with the sub-array 202 is enabled according to the decoding signal Decode. However, the other AF drivers 421, 42x connected with the other sub-arrays 201, 20x are disabled. In other words, only the AF driver 422 outputs the program voltage V_{PP} to the antifuse control line AF₂. Since the other AF drivers 421, 42x are disabled, the AF drivers 421, 42x do not outputs the program voltage V_{PP} to the antifuse control lines AF₁, AFₓ. For example, the antifuse control lines AF₁, AFₓ receive the ground voltage (0V).

Furthermore, according to the decoding signal Decode, the WL driver 440 outputs the on voltage V_{ON} to the word line WLₘ₊₁, and the WL driver 440 outputs the off voltage VOFF to other word lines. Consequently, the first row in the sub-array 202 is the selected row. Furthermore, the BL driver 450 outputs the ground voltage (0V) to the bit line BLₙ, and the other bit lines are in the floating state. Consequently, in the sub-array 202, the memory cell c_{2,1n} in the first row is the selected memory cell. The selected memory cell c_{2,1n} generates a program current 1P. In addition, the selected memory cell c_{2,1n} is programmed to the ruptured state.

Furthermore, according to the decoding signal Decode, the BL driver 450 may also output the ground voltage (0V) to more bit lines. For example, when the program action is performed, the BL driver 450 outputs the ground voltage (0V) to the bit line BL₁ and the bit line BLₙ. The other bit lines are in the floating state. Meanwhile, the memory cell c_{2,11} and the memory cell c_{2,1n} are selected memory cells, and these two selected memory cells are programmed into the ruptured state.

FIG. 5B is a schematic timing waveform diagram illustrating associated signals of the antifuse-type non-volatile memory of the second embodiment in the program mode. When the antifuse-type non-volatile memory enters the program mode, multiple program actions can be performed. During each program action, the memory cell is selected according to the decoding signal Decode. Consequently, the corresponding AF driver is enabled, and the program action is performed on the selected memory cell.

Each program action includes a program cycle. After the program cycle, the selected memory cell will be programmed to the ruptured state. As shown in FIG. 5B, the time period between the time point t_{A} and the time point t_{C} is the program cycle of one program action. That is, the program action starts at the time point t_{A}, and the program action ends at the time point t_{C}. Of course, after the time point t_{C}, another program action is performed again, and another program cycle starts.

Please refer to FIG. 5B. Before the time point t_{A} (i.e., before the program cycle), the AF driver 422 does not output the program voltage V_{PP} to the antifuse control line AF₂, and the WL driver 440 does not output the on voltage V_{ON} to the word line WLₘ₊₁. In addition, the voltage on the following control lines FL₂ is the conducting voltage V_{CD}.

At the time point t_{A}, according to the decoding signal Decode, the WL driver 440 outputs the on voltage V_{ON} to the word line WLₘ₊₁, the BL driver 450 outputs the ground voltage (0V) to the bit line BLₙ, the AF driver 422 outputs the program voltage V_{PP} to the antifuse control line AF₂, and the voltage on the following control lines FL₂ is maintained at the conducting voltage V_{CD}. That is, the memory cell c_{2,1n} in the sub-array 202 is the selected memory cell. Furthermore, in the program cycle, the selected memory cell c_{2,1n} will be programmed to the ruptured state.

When the antifuse-type non-volatile memory enters the program mode, the VFL power supply 264 provides the conducting voltage V_{CD} to the following control lines FL₁˜FLₓ. When the antifuse-type non-volatile memory exits the program mode, the conducting voltage V_{CD} is no longer provided to the following control lines FL₁˜FLₓ. Consequently, at the time point t_{A}, the program cycle of the program action starts. Since the following transistor has been in the conducting state, the following transistor will not be damaged regardless of the rising speed of the program voltage V_{PP} from AF driver 422. In addition, the program disturbance or the program failure will not occur. Similarly, at the time point t_{C}, the program cycle of the program action ends. In this way, the following transistor will not be damaged, and the program disturbance or the program failure will not occur.

In the antifuse-type non-volatile memory of the above embodiments, the memory cell array is composed of the memory cells of FIG. 1A. It is noted that numerous modifications may be made while retaining the teachings of the present invention. In a variant example, each antifuse-type memory cell in the sub-array of the memory cell array includes a first following transistor, a second following transistor, an antifuse transistor and a select transistor. The first following transistor and the second following transistor are coupled between the antifuse transistor and the select transistor. The gate terminal of the first following transistor is connected with a first following control line. The gate terminal of the second following transistor is connected with a second following control line.

Furthermore, the power supplying circuit of the antifuse-type non-volatile memory includes a V_{FL1} power supply and a V_{FL2} power supply. The output terminal of the V_{FL1} power supply is connected with the first following control line. The output terminal of the V_{FL2} power supply is connected with the second following control line. When the antifuse-type non-volatile memory enters the program mode, the V_{FL1} power supply provides a first on voltage to the first following control line, and the V_{FL2} power supply provides a second on voltage to the second following control line. In this way, the following transistor will not be damaged, and the program disturbance or the program failure will not occur.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. An antifuse-type non-volatile memory, comprising:
a memory cell array comprising a first sub-array and a second sub-array, wherein each of the first sub-array and the second sub-array comprises a plurality of memory cells, wherein the plurality of memory cells in the first sub-array are connected with a first antifuse control line and a first following control line, n memory cells in a first row of the first sub-array are connected with a first word line, and the n memory cells in the first row of the first sub-array are respectively connected with n bit lines, wherein the plurality of memory cells in the second sub-array are connected with a second antifuse control line and a second following control line, n memory cells in a first row of the second sub-array are connected with a second word line, and the n memory cells in the first row of the second sub-array are respectively connected with the n bit lines, wherein n is a positive integer greater than 1;
a driving circuit comprising a first antifuse control line driver, a second antifuse control line driver, a word line driver and a bit line driver, wherein the first antifuse control line driver is connected with the first antifuse control line, the second antifuse control line driver is connected with the second antifuse control line, the word line driver is connected with the first word line and the second word line, and the bit line driver is connected with the n bit lines;
a first voltage power supply, wherein an output terminal of the first voltage power supply is connected with the first antifuse control line driver and the second antifuse control line driver; and
a second voltage power supply, wherein an output terminal of the second voltage power supply is connected with the first following control line and the second following control line,
wherein when the antifuse-type non-volatile memory enters a program mode, the first voltage power supply provides a program voltage to the first antifuse control line driver and the second antifuse control line driver, and the second voltage power supply provides a conducting voltage to the first following control line and the second following control line,
wherein when the antifuse-type non-volatile memory enters the program mode, and before a program cycle, the first antifuse control line driver does not output the program voltage to the first antifuse control line, and the second antifuse control driver does not output the program voltage to the second antifuse control line.

2. The antifuse-type non-volatile memory as claimed in claim 1, wherein when the antifuse-type non-volatile memory enters the program mode, and in the program cycle, the first antifuse control line driver outputs the program voltage to the first antifuse control line and the second antifuse control driver does not output the program voltage to the second antifuse control line according to a decoding signal, the word line driver outputs an on voltage to the first word line and outputs an off voltage to the second word line according to the decoding signal, and the bit line driver at least provides a ground voltage to one of the n bit lines according to the decoding signal.

3. The antifuse-type non-volatile memory as claimed in claim 2, wherein in the program cycle, the first row of the first sub-array is a selected row, and at least one memory cell of the n memory cells in the selected row is programmed into a ruptured state.

4. The antifuse-type non-volatile memory as claimed in claim 1, wherein each of the first sub-array and the second sub-array comprises m×n memory cells, wherein the m×n memory cells in the first sub-array are connected with the first antifuse control line and the first following control line, wherein the m×n memory cells in the second sub-array are connected with the second antifuse control line and the second following control line, wherein m is a positive integer greater than 1.

5. The antifuse-type non-volatile memory as claimed in claim 1, wherein when the antifuse-type non-volatile memory exits the program mode, the second voltage power supply stops providing the conducting voltage to the first following control line and the second following control line.

6. The antifuse-type non-volatile memory as claimed in claim 1, wherein the antifuse-type non-volatile memory further comprises a third voltage power supply, and the third voltage power supply is connected with the word line driver, wherein when the antifuse-type non-volatile memory enters the program mode, the third voltage power supply provides an on voltage to the word line driver.

7. The antifuse-type non-volatile memory as claimed in claim 1, wherein the n memory cells in the first row of the first sub-array comprises a first memory cell, and the first memory cell comprises:
an antifuse transistor, wherein a first drain/source terminal of the antifuse transistor is in a floating state, and a gate terminal of the antifuse transistor is connected with the first antifuse control line;
a following transistor, wherein a first drain/source terminal of the following transistor is connected with a second drain/source terminal of the antifuse transistor, and a gate terminal of the following transistor is connected with the first following control line; and
a select transistor, wherein a first drain/source terminal of the select transistor is connected with a second drain/source terminal of the following transistor, a gate terminal of the select transistor is connected with the first word line, and a second drain/source terminal of the select transistor is connected with a first bit line of the n bit lines.

8. The antifuse-type non-volatile memory as claimed in claim 1, wherein the driving circuit further comprises a third antifuse control line driver, which is connected with the output terminal of the first voltage power supply, wherein the memory cell array further comprising a third sub-array, the third sub-array comprises a plurality of memory cells, the plurality of memory cells in the third sub-array are connected with a third antifuse control line and a third following control line, n memory cells in a first row of the third sub-array are connected with a third word line, and the n memory cells in the first row of the third sub-array are respectively connected with the n bit lines, wherein third word line is connected with the word line driver, the third antifuse control line is connected with the third antifuse control line driver, and the third following control line is connected with the output terminal of the second voltage power supply.
